(19) United States
(12) Patent Application Publication
(10) Pub. No.: US 2011/0115074 A1
(43) Pub. Date: May 19, 2011

(54) WAFER BUMPING USING PRINTED UNDER BUMP METALIZATION

(75) Inventors: Kunzhong (Kevin) Hu, Irvine, CA (US); Edward Law, Ladera Ranch, CA (US)

(73) Assignee: BROADCOM CORPORATION, Irvine, CA (US)

(21) Appl. No.: 12/730,609

(22) Filed: Mar. 24, 2010

Related U.S. Application Data
(60) Provisional application No. 61/260,971, filed on Nov. 13, 2009.

(51) Int. Cl. H01L 23/498; H01L 21/60; B41J 2/17

(52) U.S. Cl. 257/737; 438/614; 347/95; 257/E21.508; 257/E23.068

(57) ABSTRACT

Methods, systems, and apparatuses for printing under bump metallization (UBM) features on chips/wafers are provided. A wafer is received that has a surface defined by a plurality of integrated circuit regions. Each integrated circuit region has a passivation layer and a plurality of terminals on the surface of the wafer accessible through openings in the passivation layer. A plurality of UBM features are formed on the surface of the wafer in the form of an ink such that each UBM feature is formed electrically coupled with a corresponding terminal of the plurality of terminals. An ink jet printer may be used to print the ink in the form of the UBM feature. A UBM feature may be formed directly on a corresponding terminal, or on routing that is coupled to the corresponding terminal. A bump interconnect may be formed on the UBM feature.

This application claims the benefit of U.S. Provisional Application No. 61/260,971, filed on Nov. 13, 2009, which is incorporated by reference herein in its entirety.

### BACKGROUND OF THE INVENTION

1. Field of the Invention

The present invention relates to integrated circuit packaging technology.

2. Background Art

Integrated circuit (IC) chips or dies are typically interfaced with other circuits using a package that can be attached to a printed circuit board (PCB). One such type of IC die package is a ball grid array (BGA) package. BGA packages provide for smaller footprints than many other package solutions available today. A BGA package has an array of solder ball pads located on a bottom external surface of a package substrate. Solder balls are attached to the solder ball pads. The solder balls are reflowed to attach the package to the PCB.

In some BGA packages, a die is attached to the substrate of the package (e.g., using an adhesive), and signals of the die are interfaced with electrical features (e.g., bond fingers) of the substrate using wire bonds. In such a BGA package, wire bonds are connected between signal pads/terminals of the die and electrical features of the substrate. In another type of BGA package, which may be referred to as a “flip chip package,” a die may be attached to the substrate of the package in a “flip chip” orientation. In such a BGA package, solder bumps are formed on the signal pads/terminals of the die, and the die is inverted (“flipped”) and attached to the substrate by reflowing the solder bumps so that they attach to corresponding pads on the surface of the substrate.

An advanced type of integrated circuit package is a wafer-level BGA package. Wafer-level BGA packages have several names in industry, including wafer level chip scale packages (WLCSP), among others. In a wafer-level BGA package, the solder bumps/balls are mounted directly to I/O pads/terminals of the IC chip when the IC chip has not yet been singulated from its fabrication wafer. Wafer-level BGA packages can therefore be made very small, with high pin out, relative to other IC package types including traditional BGA packages.

Attaching solder balls or bumps to the signal pads of the dies in flip chip and wafer-level packages is a difficult process. The signal pads typically are coated with one or more layers of metal so that the solder bumps will adhere to the signal pads. In some cases, the I/O pads of an IC die are too close together to have solder bumps formed directly on them. As such, redistribution layers may be formed on the IC die to provide redistributed access to the I/O pads. A redistribution layer is a type of routing formed on an IC die between an I/O pad and another region of the die at which the solder bump may be formed. However, processes for attaching solder balls/solder bumps to the terminals and/or redistribution layers have disadvantages, including being complex, expensive, time consuming, and not environmentally friendly.

### BRIEF SUMMARY OF THE INVENTION

Methods, systems, and apparatuses are described for printing under bump metallization (UBM) features on dies (which may or may not be in-wafer) substantially as shown in and/or described herein in connection with at least one of the figures, as set forth more completely in the claims.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a flowchart providing example steps for performing wafer-level package processing.

FIG. 2 shows a plan view of an example wafer.

FIG. 3 shows a cross-sectional view of a wafer, including an example integrated circuit region of the wafer.

FIG. 4 shows a cross-sectional view of a solder bump or ball formed on a wafer.

FIGS. 5-7 illustrate cross-sectional views of UBM features and solder bumps formed on substrates according to example techniques.

FIGS. 8-10 show side cross-sectional views of an example wafer bumping process being used to form a solder bump on a UBM feature.

FIG. 11 shows a block diagram of a UBM feature printing system, according to an example embodiment.

FIG. 12 shows a cross-sectional view of a portion of a wafer with a UBM feature printed thereon, according to an example embodiment.

FIG. 13 shows a flowchart providing example steps for processing a wafer to form package interconnects, according to an example embodiment.

FIG. 14 shows an integrated circuit packaging system, according to an example embodiment.

FIG. 15 shows a view of a surface of a wafer, according to an example embodiment.

FIG. 16 shows a process for printing UBM features, according to an example embodiment.

FIG. 17 shows a flowchart for forming routing interconnects and printing UBM features, according to an example embodiment.

FIG. 18 shows cross-sectional view of a portion of a wafer in which a routing interconnect is formed on a surface of a wafer and a UBM feature is formed on the routing interconnect, according to an example embodiment.

FIG. 19 shows a cross-sectional view of a portion of a wafer that includes a multi-layer UBM feature, according to an example embodiment.

FIG. 20 shows a block diagram of an ink jet print head, according to an example embodiment.

FIG. 21 shows a cross-sectional view of a wafer portion, according to an example embodiment.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### Examples of Integrated Circuit Package Processing

In some integrated circuit packages, such as BGA packages, a die is attached to the substrate of the package (e.g., using an adhesive), and signals of the die are interfaced with electrical features (e.g., bond fingers) of the substrate using wire bonds. In such a package, wire bonds may be connected between signal pads/terminals of the die and electrical features of the substrate. In another type of package, which may be referred to as a “flip chip package,” a die may be attached to the substrate of the package in a “flip chip” orientation. In such a package, solder bumps are formed on the signal pads/terminals of the die, and the die is inverted (“flipped”) and attached to the substrate by reflowing the solder bumps so that they attach to corresponding pads on the surface of the substrate.

“Wafer-level packaging” is an integrated circuit packaging technology where packaging-related interconnects are applied while the integrated circuit dies or chips are still in wafer form. After the packaging-related interconnects are applied, the wafer may be tested and singulated into individual devices, and may be sent to customers for their use. Thus, individual packaging of discrete devices is not required. The size of the final package is essentially the size of the corresponding chip, resulting in a very small package solution. Wafer-level packaging is becoming increasingly popular as the demand for increased functionality in small form-factor devices increases. These applications include mobile devices such as cell phones, smart phones, mobile computers, portable music players, etc.

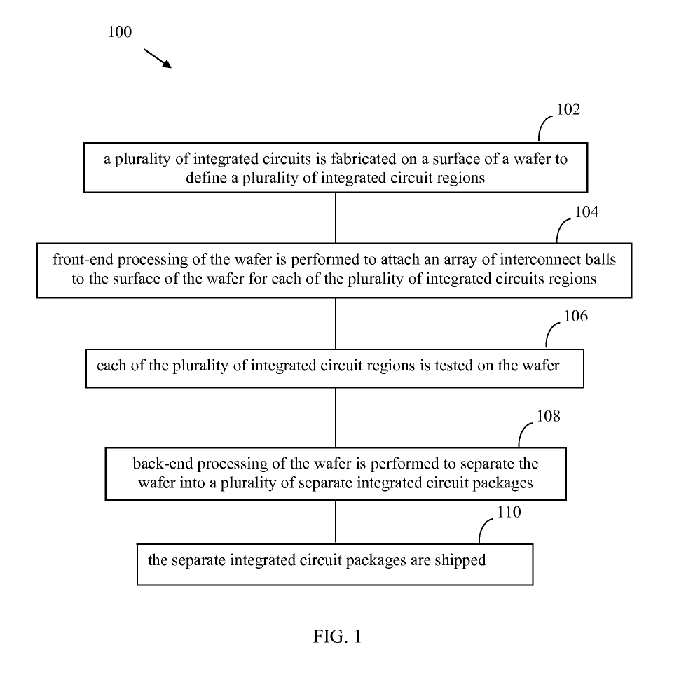

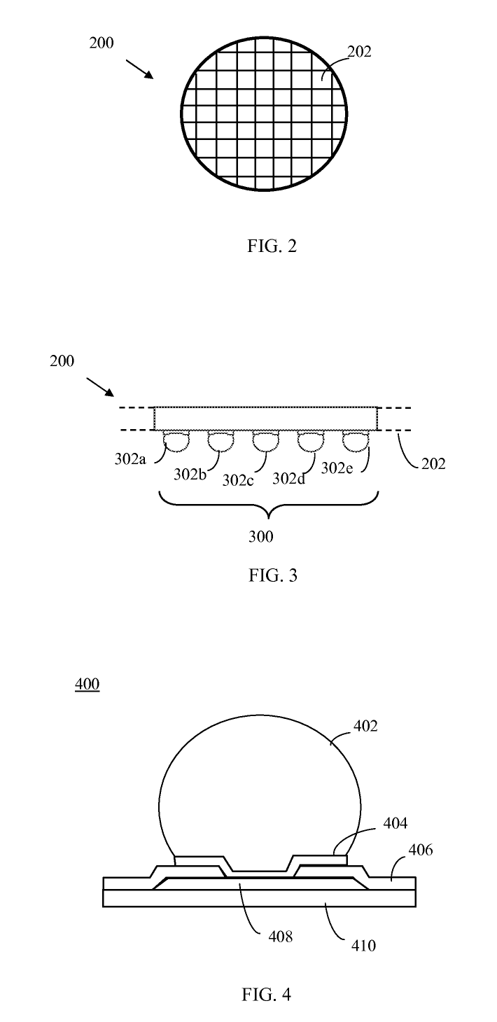

FIG. 1 shows a flowchart 100 providing example steps for performing wafer-level package processing. Flowchart 100 begins with step 102. In step 102, a plurality of integrated circuits is fabricated on a surface of a wafer to define a plurality of integrated circuit regions. For example, FIG. 2 shows a plan view of a wafer 200. Wafer 200 may be silicon, gallium arsenide, or other wafer type. As shown in FIG. 2, wafer 200 has a surface 202 defined by a plurality of integrated circuit regions (shown as small rectangles in FIG. 2). Each integrated circuit region is configured to be packaged separately into a separate wafer-level ball grid array package according to the process of flowchart 100.

In step 104, front-end processing of the wafer is performed to attach an array of interconnect balls to the surface of the wafer for each of the plurality of integrated circuits regions. A critical part of wafer-level packaging is the front-end process of step 104. In step 104, appropriate interconnects and packaging materials are applied to the wafer. For example, FIG. 3 shows a cross-sectional side view of wafer 200, highlighting an integrated circuit region 300. As shown in FIG. 3, integrated circuit region 300 has a plurality of interconnect balls (or bumps) 302a-302e attached thereto on surface 202. Interconnect balls 302a-302e may be solder, other metal, combination of metals/alloy, etc. Interconnect balls 302 are used to interface the package resulting from integrated circuit region 300 with an external device, such as a PCB.

In step 106, each of the plurality of integrated circuits regions is tested on the wafer. For example, each integrated circuit region can be interfaced with probes at interconnect balls 302 to provide ground, power, and test input signals, and to receive test output signals.

In step 108, back-end processing of the wafer is performed to separate the wafer into a plurality of separate integrated circuit packages. Examples of back-end processing may include backgrinding (thinning) of the wafer, singulating the wafer into a plurality of separate integrated circuit packages, and packing the separated integrated circuit packages for shipping (e.g., placing the separated integrated circuit packages in one or more tapes/reels, individual packaging, or other transport mechanism, for shipping packages to customers, etc.).

In step 110, the separate integrated circuit packages are shipped. For example, the separate integrated circuit packages may be shipped to a warehouse, to customers, to a site for assembly into devices, to a site for further processing, etc.

Note that a similar process to flowchart 100 may be used to fabricate flip chip packages. For example, in a flip chip package assembly process, the testing of step 106 may or may not be performed on the wafer. In step 108, the wafer is separated into a plurality of separate flip chip dies/chips. A step may be performed to mount each of the flip chip dies onto a corresponding package substrate, which may already have solder balls formed thereon (or the solder balls may be added later) to form a plurality of flip chip packages.

The front-end process of step 104 is critical to forming a reliable IC package. Aspects of the front-end process of step 104 may be performed differently, depending on factors such as the way the wafer is fabricated, etc. For example, terminals of the integrated circuit regions of the wafer may need plating to facilitate attachment of the interconnect balls. Under bump metallization (UBM) layers are typically one or more metal layers formed (e.g., metal deposition—plating, sputtering, etc.) to provide a robust interface between terminals (and/or redistribution layers (RDLs)) and a package interconnect mechanism (such as a bump interconnect). An RDL is a type of routing that may be formed on an IC die between an I/O pad and another region of the die at which the solder bump may be formed. A UBM layer serves as a solderable layer for a solder package interconnect mechanism. Furthermore, a UBM provides protection for underlying metal or circuitry from chemical/thermal/electrical interactions between the various metals/alloys used for the package interconnect mechanism (e.g., may include one or more “barrier layers”).

Flip chip packages and wafer level packages are more and more popular, becoming a popular trend in IC packaging. Using flip chip packages or wafer level packages can achieve smaller, thinner, better performance and lower cost IC package. To achieve such types of packages, the wafer is “bumped” to attach bump interconnects. Typically a wafer bumping process includes an UBM fabrication process. For instance, FIG. 4 shows a cross-sectional view of a portion 400 of a wafer (such as wafer 200) with a UBM feature 404 and solder ball 402 formed thereon. As shown in FIG. 4, wafer portion 400 includes a wafer substrate 410, a passivation layer 406, a terminal or pad 408, UBM feature 404, and solder ball or bump 402. Wafer substrate 410 may be made of any suitable wafer material, such as silicon or gallium arsenide. Terminal 408 is an I/O (input/output) pad for an integrated circuit chip/die included in the wafer, and thus may be electrically coupled to an internal signal of the wafer. Terminal 408 may be made of a metal, such as aluminum or copper, or a combination of metals/alloy. Terminal 408 may be a portion of a redistribution layer or may be a metalized I/O pad. Passivation layer 406 is formed on substrate 410 and terminal 408, with an opening being formed through passivation layer 406 so that at least a portion of terminal 408 is accessible. UBM feature 404 is formed on passivation layer 406 and in contact with terminal 408 through the opening through passivation layer 406. Solder bump 402 is formed on UBM feature 404.

UBM features, such as UBM feature 404, may be formed in various ways. Some example UBM fabrication processes are described as follows. One example of such a process is an “electro-less process.” The electro-less process is a chemical technique used to deposit a metal (e.g., nickel or gold) as a UBM layer on a wafer, where the wafer is deposited in a chemical bath containing the metal. No mask is required to be applied to the wafer prior to the electro-less metal deposition. The electro-less process is limited in how thick of a metal layer can be deposited, however.

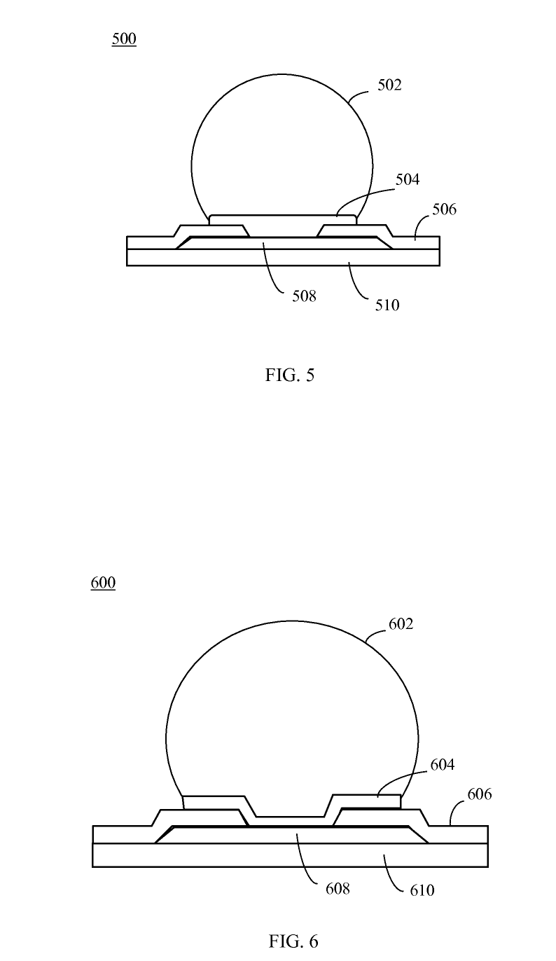

FIG. 5 shows a cross-sectional view of a wafer portion 500 that includes a UBM feature 504 formed according to an electro-less process. Wafer portion 500 is structured generally similar to wafer portion 400 of FIG. 4. As shown in FIG. 5, wafer portion 500 includes a wafer substrate 510, a passivation layer 506, a terminal or pad 508, UBM feature 504, and solder ball or bump 502. UBM feature 504 is formed on passivation layer 506 and terminal 508 using an electro-less process. For example, UBM feature 504 may be a nickel or gold plate. As shown in FIG. 5, UBM feature 504 is concentrated over terminal 508. Solder bump 502 is formed on UBM feature 504.

Another example UBM forming process is a “sputtering process.” According to the sputtering process, an ion beam is directed at a target metal, which causes metal particles to be emitted from the target metal, which adhere to an adjacent wafer. One or more metal layers may be sputtered onto the wafer through a mask to form patterned UBM layers on the wafer.

FIG. 6 shows a cross-sectional view of a wafer portion 600 that includes a UBM feature 604 formed according to a sputtering process. Wafer portion 600 is structured generally similar to wafer portion 400 of FIG. 4. As shown in FIG. 6, wafer portion 600 includes a wafer substrate 610, a passivation layer 606, a terminal or pad 608, UBM feature 604, and solder ball or bump 602. UBM feature 604 is formed on passivation layer 606 and terminal 608 using a sputtering process. Solder bump 602 is formed on UBM feature 604.

Still another example UBM forming process is a “plating process.” According to the plating process, an electrical current is applied to coat a wafer with a thin layer of a metal from solution. A mask may be used to pattern the metal on the wafer to form patterned UBM features on the wafer. A plating process takes a significant amount of time. A “pillar forming process” is similar to the plating process, with the plating formed into a taller structure than typical plating. According to a pillar forming process, the plating process may be repeated to form a pillar or post of metal. The metal may be copper or other suitable metal mentioned elsewhere herein or otherwise known.

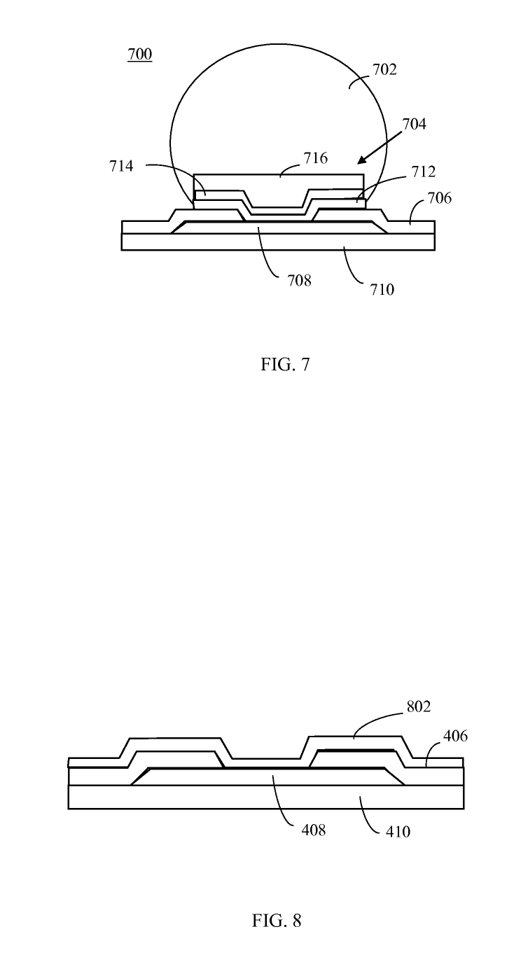

FIG. 7 shows a cross-sectional view of a wafer portion 700 that includes a UBM feature 704 formed according to a sputtering process and a pillar forming process. Wafer portion 700 is structured generally similar to wafer portion 400 of FIG. 4. As shown in FIG. 7, wafer portion 700 includes a wafer substrate 710, a passivation layer 706, a terminal or pad 708, UBM feature 704, and solder ball or bump 702. UBM feature 704 includes a first UBM layer 712 (e.g., titanium-tungsten) formed on passivation layer 706 and terminal 708 using a sputtering process, a second UBM layer 714 (e.g., copper) formed on first UBM layer 712 using a sputtering process, and stud or pillar 716 (e.g., copper) formed on second UBM layer 714 using a pillar forming process. Solder bump 702 is formed on UBM feature 704.

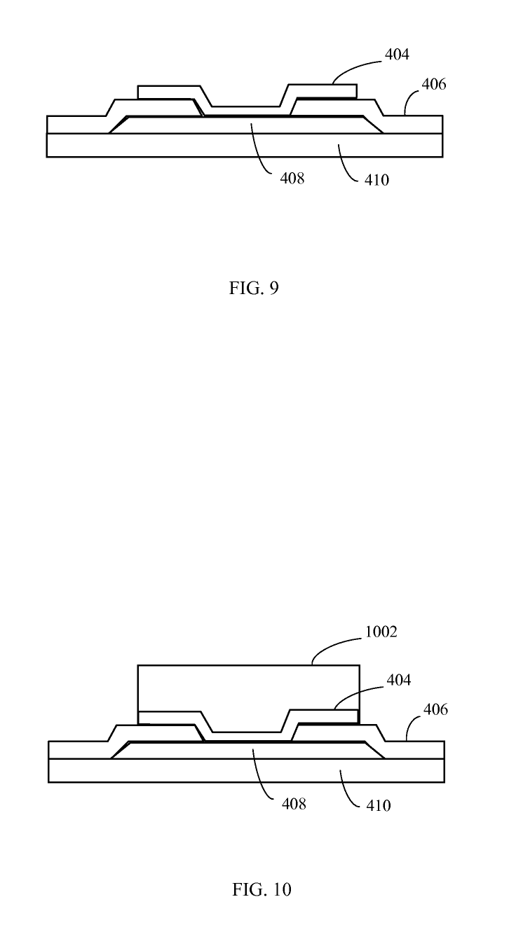

FIGS. 8-10 show side cross-sectional views of wafer portion 400 of FIG. 4 at different steps of a sputtering process used to form UBM feature 404. As shown in FIG. 8, a UBM layer 802 is formed by sputtering over passivation layer 406 and in contact with terminal 408 through the opening through passivation layer 406. For example, UBM layer 802 may include three layers (e.g., a first layer of aluminum, a second layer of nickel-vanadium, and a third layer of copper) that are each formed by sputtering. In FIG. 9, UBM layer 802 of FIG. 8 has been patterned to form UBM feature 404 in a region on terminal 408 and on passivation layer 406 around terminal 408. UBM layer 802 may be patterned in any suitable manner, including by etching, etc. UBM feature 404 may have a circular shape, an elliptical shape, a rectangular shape, or any other shape as desired for a particular application. In FIG. 10, a solder material 1002 is shown deposited on UBM feature 404. Solder material 1002 may include any solder material such as a metal (e.g., lead, etc.) or combination of metals/alloy. Solder material 1002 of FIG. 10 may be heated and reflowed to form a rounded solder bump 402 on UBM feature 404, as shown in FIG. 4.

Disadvantages exist with some UBM forming processes, such as the processes described above. For example, such processes typically require various etching, photo development, clean processes, as well as masks. Such processes typically have a long cycle time, which can be several days. Due to the long cycle time, masks, and expensive equipment that are used, such processes can be expensive. Furthermore, such processes are typically not environmentally friendly (e.g., disposal of used chemicals is required). Still further, many wafer design considerations have to be taken into account (e.g., seal rings, scribes, passivation, etc.).

### Example Printed UBM Embodiments

According to embodiments, circuit printing technology is used to print UBM features on wafer I/O metal instead of using traditional technologies. For instance, an ink jet printer can be used to print an electrically conductive ink (e.g., a metal, a nanopaste, a metal nanopaste, etc.) to form one or more layers on the wafer terminal to form UBM features. Furthermore, in an embodiment, solder bumps/balls and/or pillars/posts/studs may be printed using an ink jet printer.

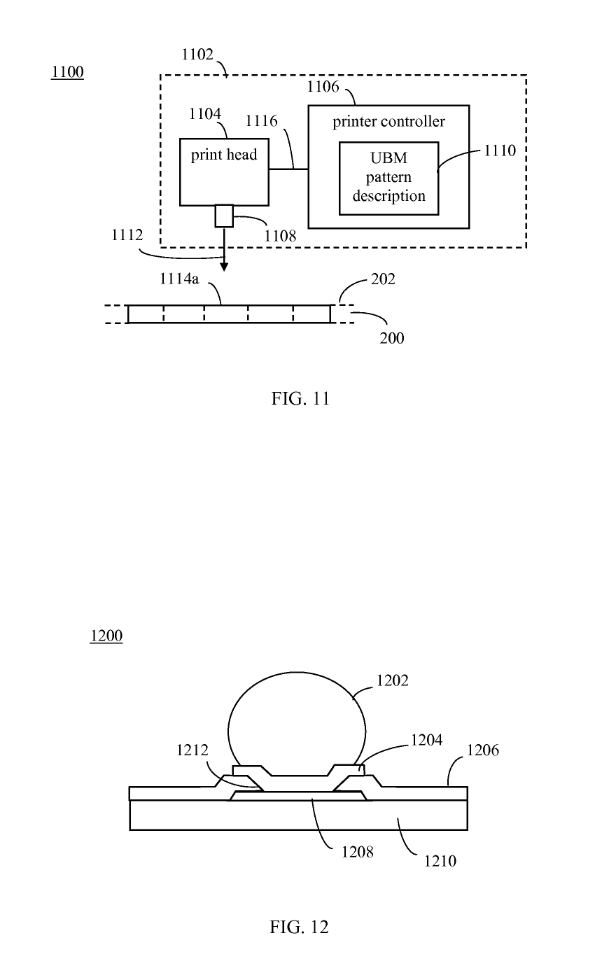

For instance, FIG. 11 shows a block diagram of a UBM feature printing system 1100 according to an example embodiment. As shown in FIG. 11, system 1100 includes an ink jet printer 1102. Ink jet printer 1102 is configured to print UBM features on substrates, such as on surface 202 of wafer 200. As shown in FIG. 11, ink jet printer 1102 includes a print head 1104 and a printer controller 1106. Ink jet printer 1102 may include any number of print heads 1104 that are coupled to printer controller 1106. System 1100 is described as follows.

As shown in FIG. 11, printer controller 1106 stores a UBM pattern description 1110. UBM pattern description 1110 may be an electronic file or other entity that includes a description of a pattern of UBM features to be printed on wafer 200. For example, UBM pattern description 1110 may indicate a geometry (e.g., a shape, size, position, and/or thickness) of each UBM feature to be printed on surface 202 of wafer 200. Furthermore, UBM pattern description 1110 may indicate a number of one or more layers to be printed for each UBM feature, a material (e.g., a specific ink) for each layer, as well as the geometry of each layer. Logic (e.g., circuitry, one or more processors, etc.) of printer controller 1106 is configured to read UBM pattern description 1110 and to control print head 1104 to form UBM features as indicated by UBM pattern description 1110.

As shown in FIG. 11, wafer 200 includes a plurality (e.g., an array) of integrated circuit regions 1114 (an integrated circuit region 1114a is indicated in FIG. 11 for illustrative purposes) that each correspond to a die (when separated from wafer 200). UBM pattern description 1110 may include a UBM feature pattern for one or more integrated circuit regions 1114 of wafer 200, including the entirety of wafer 200. When UBM pattern description 1110 includes a UBM feature pattern for an integrated circuit region 1114, ink jet printer 1102 may print the UBM feature pattern multiple times on wafer 200 if the pattern of integrated circuit region 1114 repeats in wafer 200. When UBM pattern description 1110 includes a UBM feature pattern for an entirety of wafer 200, UBM pattern description 1110 may include a repeating UBM feature pattern corresponding to a repeating pattern of integrated circuit region 1114 on wafer 200, and/or may include different UBM feature patterns corresponding to different integrated circuit region patterns 1114 on wafer 200.

In an embodiment, printer controller 1106 may include or be coupled to a computer-readable medium (e.g., one or more memory devices, a hard drive, and/or other computer readable storage device(s)) that stores UBM pattern description 1110. Ink jet printer 1102 may receive one or more UBM pattern descriptions 1110 over a network to be stored therein, and used to print UBM features on one or more wafers. Thus, ink jet printer 1102 is reconfigurable to be enabled to accommodate different UBM feature patterns for different wafers.

As shown in FIG. 11, printer controller 1106 is coupled to print head 1104 by a control signal 1116. Control signal 1116 includes control instructions to one or more print heads 1104 to cause UBM pattern features to be printed on wafer 200 according to UBM pattern description 1110. Print head 1104 may be moved (e.g., laterally along X and Y axes parallel to surface 202, and/or along a Z axis perpendicular to surface 202) according to control signal 1116. As shown in FIG. 11, print head 1104 includes a print port 1108, which may be selectively opened to emit an ink 1112 from print head 1104 according to control signal 1116. Print port 1108 may have an opening width corresponding to a UBM feature width, or may have an opening width that is narrower than a UBM feature width. In one example, multiple passes of print port 1108 to print ink in adjacent locations may be used to print a pattern that is as wide as a UBM feature width. For example, print port 1108 may have an opening width in a micron scale (e.g., less than a micron, single microns, tens of microns, hundreds of microns) to print micron scale UBM features. A speed of movement of print head 1104, a rate of flow of ink 1112 from port 1108, and/or a number of print passes may be used/modified to print thinner or thicker UBM feature layers, as desired.

System 1100 may be configured to print various configurations of UBM features, in embodiments. For instance, FIG. 12 shows a cross-sectional view of a portion 1200 of a wafer (such as wafer 200) with a UBM feature 1204 printed thereon, according to an example embodiment. As shown in FIG. 12, wafer portion 1200 includes a wafer substrate 1210, a passivation layer 1206, a terminal or pad 1208, UBM feature 1204, and a bump interconnect 1202. Wafer substrate 1210 may be made of any suitable wafer material, such as silicon or gallium arsenide. Terminal 1208 is an I/O (input/output) pad for an integrated circuit chip/die included in the wafer, and thus may be electrically coupled to an internal signal of the wafer. Terminal 1208 may be made of a metal, such as aluminum or copper, or a combination of metals/alloy. Passivation layer 1206 is formed on substrate 1210 and terminal 1208, with an opening 1212 being formed (e.g., etched) through passivation layer 1206 so that at least a portion of terminal 1208 is accessible. Passivation layer 1206 may be formed of any suitable passivation material, such as a layer of an oxide or nitride.

UBM feature 1204 is printed on passivation layer 1206 and in contact with terminal 1208 through opening 1212 through passivation layer 1206. For example, referring to FIG. 11, UBM feature 1204 may be formed by ink jet printer 1102 printing ink 1112 on wafer portion 1200 of FIG. 12 in the pattern of UBM feature 1204. For instance, UBM feature 1204 may be printed on terminal 1208 to cover terminal 1208 in opening 1212, and may optionally be printed to overlap passivation layer 1206 around opening 1212 as shown in FIG. 12. UBM feature 1204 may be a solidified version of ink 1112.

As shown in FIG. 12, bump interconnect 1202 is formed on UBM feature 1204. Bump interconnect 1202 may be a ball or bump, or other suitable bump interconnect mechanism. Bump interconnect 1202 may be formed on UBM feature 1204 in any way, including by ball drop, by applying a reflowing solder, or in any other conventional manner. In an embodiment, bump interconnect 1202 may be formed by ink jet printer 1102 printing ink 1112 on UBM feature 1204 (and using a subsequent reflow process).

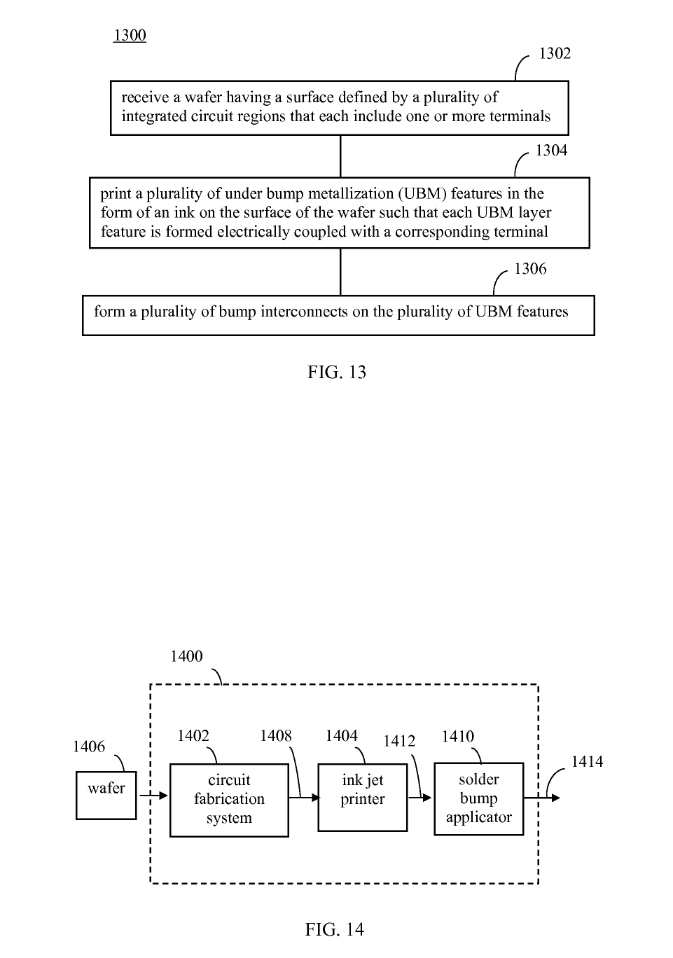

For instance, FIG. 13 shows a flowchart 1300 providing example steps for processing a wafer to form packaging interconnects, according to an example embodiment. For instance, flowchart 1300 may be performed during step 104 of flowchart 100 (FIG. 1). For illustrative purposes, flowchart 1300 is described with reference to various figures, including FIG. 14. FIG. 14 shows an integrated circuit packaging system 1400, according to an example embodiment. As shown in FIG. 14, system 1400 includes a circuit fabrication system 1402, an ink jet printer 1404, and a solder bump applicator 1410. Other structural and operational embodiments will be apparent to persons skilled in the relevant art(s) based on the discussion provided herein.

As shown in FIG. 14, a wafer 1406 is received by circuit fabrication system 1402 of system 1400. In an embodiment, circuit fabrication system 1402 may be used to perform step 102 of flowchart 100, as described above. Circuit fabrication system 1402 is configured to fabricate integrated circuits on a surface of wafer 1406 to define a plurality of integrated circuit regions, such as integrated circuit regions 1114 shown in FIG. 11. Circuit fabrication system 1402 may include any type of integrated circuit fabrication functionality, including a photolithography system. Circuit fabrication system 1402 outputs a wafer with integrated circuit regions 1408. For instance, wafer 200 shown in FIG. 2 is an example of wafer with integrated circuit regions 1408.

Referring to flowchart 1300 (FIG. 13), in step 1302, a wafer is received having a surface defined by a plurality of integrated circuit regions that each include one or more terminals. For instance, as shown in FIG. 14, wafer with integrated circuit regions 1408 is received by ink jet printer 1404. Ink jet printer 1404 is an example of ink jet printer 1102 shown in FIG. 11. Referring to FIG. 2, wafer 200, which is an example of wafer with integrated circuit regions 1408, has a surface 202 defined by a plurality of integrated circuit regions (shown as small rectangles in FIG. 2). Furthermore, wafer 200 is shown in FIG. 11 having integrated circuit regions 1114. Each integrated circuit region is configured to be packaged separately into integrated circuit package (e.g., a flip chip package, a wafer-level IC package, etc.).

In step 1304, a plurality of under bump metallization (UBM) features is printed in the form of an ink on the surface of the wafer such that each UBM feature is formed electrically coupled with a corresponding terminal. For instance, ink jet printer 1404 shown in FIG. 14 may print UBM features on the surface of a wafer in contact with terminals. As shown in FIG. 14, ink jet printer 1404 outputs a wafer with printed UBM features 1412. Referring to FIG. 11, ink jet printer 1102 may be configured to print UBM features, such as UBM feature 1204 of FIG. 12, in the form of ink 1112 in one or more integrated circuit regions 1114 of wafer 200. As shown in FIG. 12, UBM feature 1204 is printed in contact with terminal 1208. UBM feature 1204 may be a solidified form of ink 1112 of FIG. 11.

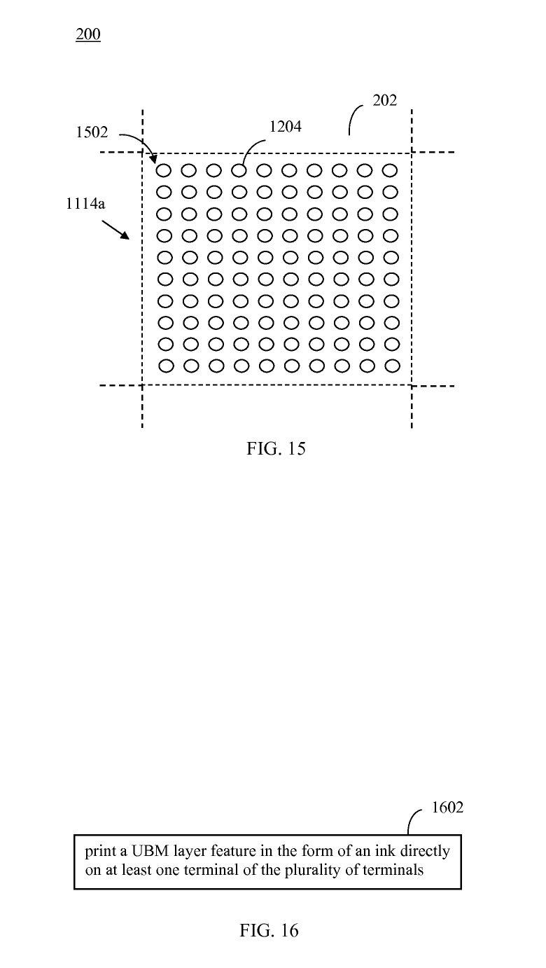

An ink jet printer may print UBM features in any desired pattern. For instance, FIG. 15 shows a view of surface 202 of wafer 200, according to an example embodiment. An integrated circuit region 1114a of wafer 200 is indicated in FIG. 15 (by a dotted line rectangle). As shown in FIG. 15, a UBM feature array 1502 is printed in integrated circuit region 1114a. UBM feature array 1502 is an example of a regular array of UBM features 1204. UBM feature array 1502 is shown including a ten by ten array (one hundred) of UBM features 1204. UBM feature array 1502 is shown for purposes of illustration, and any size array of UBM features 1204 may be printed, in embodiments. Furthermore, in embodiments, UBM features 1204 may be printed in other patterns than a regular array, including a staggered array, or may be printed in any non-array pattern.

In an embodiment, ink jet printer 1102 is an ink jet printer configured to print ink 1112 that is an electrically conductive ink. Examples of electrically conductive inks include those described elsewhere herein, such as a metal-based ink and/or a nanopaste, or other suitable electrically conductive inks known to persons skilled in the relevant art(s). A nanopaste may include nano-scale particles of silver, copper, platinum, aluminum, gold, nickel, tin, lead, palladium, and/or other metal and/or metal alloy, that is dispersed in a carrier (e.g., a solvent). In embodiments, the nanopaste is configured to have a viscosity and/or surface tension suitable for ink jet printing onto a wafer substrate, and is configured to adhere to a wafer substrate.

For instance, in an embodiment, the nanopaste may include nano-scale silver (and/or other metal) particles uniformly dispersed in a polar or non-polar solvent to form a high solid content/high viscosity ink. Suitable carriers may be selected, depending on the particular nanopaste and the desired application, and may include organic carriers, aqueous carriers and mixtures of organic and aqueous liquids. In another embodiment, the nanopaste is an inorganic nanopaste including inorganic nanoparticles in a substantially aqueous carrier. In an embodiment, the carrier may be composed of water or mixtures of water with water-miscible organic solvents such as suitable alcohols. Suitable examples of the nanopastes described herein include a silver/palladium sol having a metallic particle average diameter of 11.1 nm, which is supplied in a 5 w/w % solution in water by Advanced Nano Products (ANP) Co., Chungcheongbukdo, Korea. Another example is a silver sol having a metallic particle average diameter of 11.0 nm, which is supplied in a 5 w/w % solution in water by ANP Co.

Ink jet printer 1102 is configured to print electrically conductive inks having a suitable viscosity and/or surface tension, and that are configured to adhere to a wafer substrate. Furthermore, ink jet printer 1102 is configured to print UBM features 1204 having a suitable width to enable a suitable pitch for bump interconnects 1202. An example pitch for bump interconnects 1102, in an embodiment, is 200 microns. In example embodiments, UBM features 1204 may have widths in the ones of microns, tens of microns, hundreds of microns, or other suitable widths (and spacings), as would be known to persons skilled in the relevant art(s). In an embodiment, a conventional ink jet printer may be configured to print electrically conductive ink as ink jet printer 1102, by replacing an ink reservoir of the conventional ink jet printer with electrically conductive ink. Furthermore, the ink jet printer may be provided with electronic routing interconnect layout information (e.g., in the form of UBM pattern description 1110) to configure the ink jet printer to print ink in a particular circuit configuration. Examples of conventionally available ink jet printers that may be adapted to be used as ink jet printer 1102 include ink jet printers manufactured by Hewlett-Packard Co., Palo Alto, Calif.

In step 1306, a plurality of bump interconnects is formed on the plurality of UBM features. As shown in FIG. 14, solder bump applicator 1410 receives wafer with printed UBM features 1412. In an embodiment, solder bump applicator 1406 of FIG. 14 may be configured to form bump interconnects 1106 on the UBM features of wafer with printed UBM features 1412. As shown in FIG. 14, solder bump applicator 1410 outputs a wafer with bump interconnects 1414.

For example, as shown in FIG. 12, bump interconnect 1202 is formed on UBM feature 1204. In the example of FIG. 15, one hundred bump interconnects 1202 may be formed on the one hundred UBM features 1204. Bump interconnects 1202 may be formed of any suitable electrically conductive material, including a metal such as a solder or solder alloy, copper, aluminum, gold, silver, nickel, tin, titanium, lead, a combination of metals/alloy, etc. Bump interconnects 1202 may have any size and pitch, as suitable for a particular application. Solder bump applicator 1410 may be configured to form bump interconnects 1202 in any manner, including by sputtering, electroplating, stencil printing, solder paste or ball loading, lithographic processes, etc., as would be known to persons skilled in the relevant art(s).

For instance, in an embodiment, bump interconnects 1202 may be printed on UBM features. For instance, in an embodiment, solder bump applicator 1410 may include an ink jet printer similar to ink jet printer 1404 to print UBM features. In another embodiment, solder bump applicator 1410 may not be present, and ink jet printer 1404 may be configured to print UBM features. In either embodiment, the ink jet printer may print a single layer of electrically conductive ink on the wafer to form bump interconnects 1202. In another embodiment, the ink jet printer may print multiple layers of electrically conductive ink on the wafer to form bump interconnects 1202 as stacks of electrically conductive ink. The ink jet printer may be configured to enable the ink printed on the wafer to cure (e.g., by allowing a suitable amount of time to pass, by applying heat, etc.), if necessary for the particular ink, prior to printing a next layer of ink, and/or prior to outputting the wafer. Subsequent to printing a desired number of layers of ink on the UBM features to form the base material for bump interconnects 1202 (e.g., as shown in FIG. 10), the base material may be heated and reflowed to form bump interconnects 1202 having a rounded shape, as in FIG. 12.

In embodiments, a UBM feature 1202 may be formed directly or indirectly on a corresponding terminal 1208 to be electrically coupled with the corresponding terminal 1208. For instance, in one embodiment, step 1602 of FIG. 16 may be performed during step 1304 of FIG. 13. In step 1602, a UBM layer feature is printed in the form of an ink directly on at least one terminal of the plurality of terminals. FIG. 12 shows an example of UBM feature 1202 that was printed directly on terminal 1208.

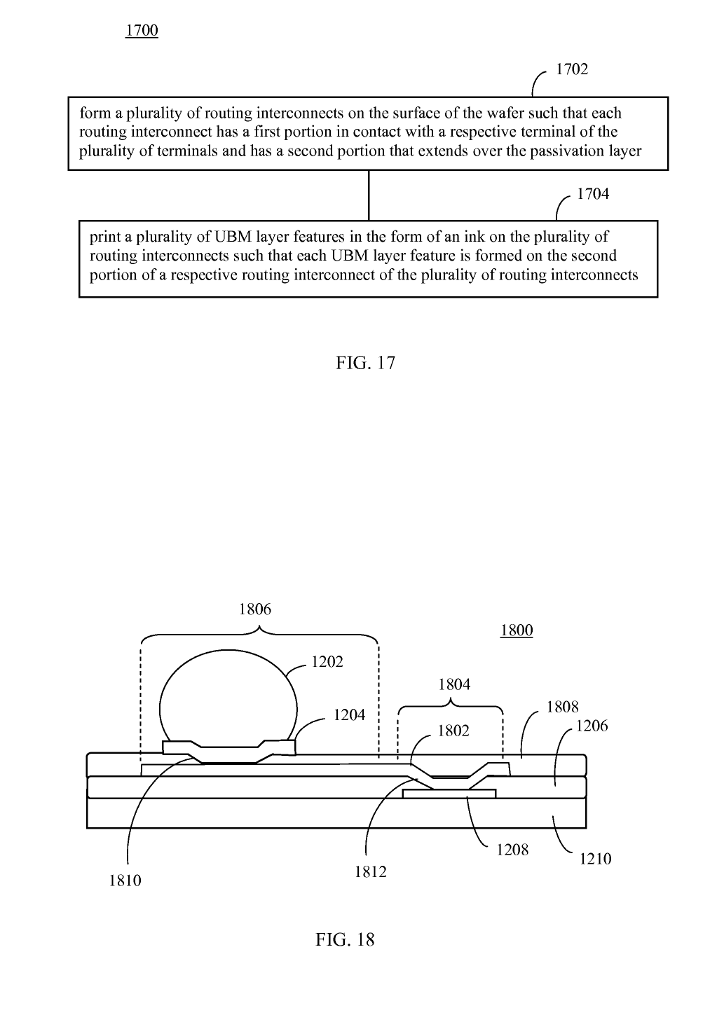

In another embodiment, flowchart 1700 of FIG. 17 may be performed. In step 1702, a plurality of routing interconnects is formed on the surface of the wafer such that each routing interconnect has a first portion in contact with a respective terminal of the plurality of terminals and has a second portion that extends over the passivation layer. In step 1704, a plurality of UBM layer features is printed in the form of an ink on the plurality of routing interconnects such that each UBM layer feature is formed on the second portion of a respective routing interconnect of the plurality of routing interconnects. For example, step 1704 may be performed during step 1304 of FIG. 13.

As an example of step 1702, FIG. 18 shows a portion 1800 of a wafer (e.g., wafer 200) in which a routing interconnect 1802 (also known as a “redistribution interconnect”) is formed on a surface of a wafer, and UBM feature 1202 is formed on routing interconnect 1802, according to an embodiment. In one example, to form routing interconnect 1802 on wafer portion 1800, passivation layer 1206 is formed on a wafer over the plurality of integrated circuits regions. Vias are formed through passivation layer 1206 at the locations of terminals, including forming opening 1812 through passivation layer 1206 over terminal 1208. An electrically conductive material (e.g., a metal or combination of metals/alloy) is formed on passivation layer 1206. One or more redistribution layers, such as routing interconnect 1802 of FIG. 18, are formed in the metal layer. For instance, as shown in FIG. 18, routing interconnect 1802 is formed to have a first portion 1804 in contact with terminal 1208 though opening 1812, and to have a second portion 1806 that extends over passivation layer 1206. A second passivation layer 1808 is formed over first passivation layer 1206 and one or more routing interconnects 1802. A second set of vias are formed through second passivation layer 1808, including forming opening 1812 through passivation layer 1808 over second portion 1806 of routing interconnect 1802. Opening 1812 provides access to second portion 1806 of routing interconnect 1802.

Subsequent to forming routing interconnect 1802, according to step 1704 of FIG. 17, UBM feature 1204 may be printed in contact with second portion 1806 of routing interconnect 1802 through opening 1812. In this manner, UBM feature 1202 is electrically coupled with terminal 1208 through routing interconnect 1802 (which is electrically conductive).

Thus, in an embodiment, routing interconnect 1802 may be formed as described above, similar to forming routing or traces on a circuit board. In another embodiment, routing interconnect 1802 may be printed in the form of an ink on wafer portion 1800. For instance, ink jet printer 1404 shown in FIG. 14 may print routing interconnects 1802 on a surface of the wafer received in step 1302. Ink jet printer 1404 may be configured to print a plurality of routing interconnects 1802 in each integrated circuit region of the received wafer, such as integrated circuit regions 1114 shown in FIG. 11.

Thus, in embodiments, an ink jet printer may print electrically conductive ink on signal terminals of a wafer to form UBM features. Such printing is more simple than conventional techniques, because photo resist/masking is not needed to pattern the UBM features, no extra etching is needed to form a UBM feature shape as in most conventional processes. An ink jet printer may print a UBM feature in a desired shape, with no extra portions of the UBM feature needing to be removed.

Embodiments can be directly applied to any package types that use wafer bumping, including wafer level packages and flip chip packages. Embodiments can be used to form UBM features, routing interconnects, pillar bumps (such as copper pillar), solder bumps, etc. Any shape of UBM feature can be printed, including a round shape (e.g., as shown in FIG. 15), an elliptical shape, a rectangular shape, etc. The printing thickness can vary. If thicker layers are desired, multiple printings can be performed, for example.

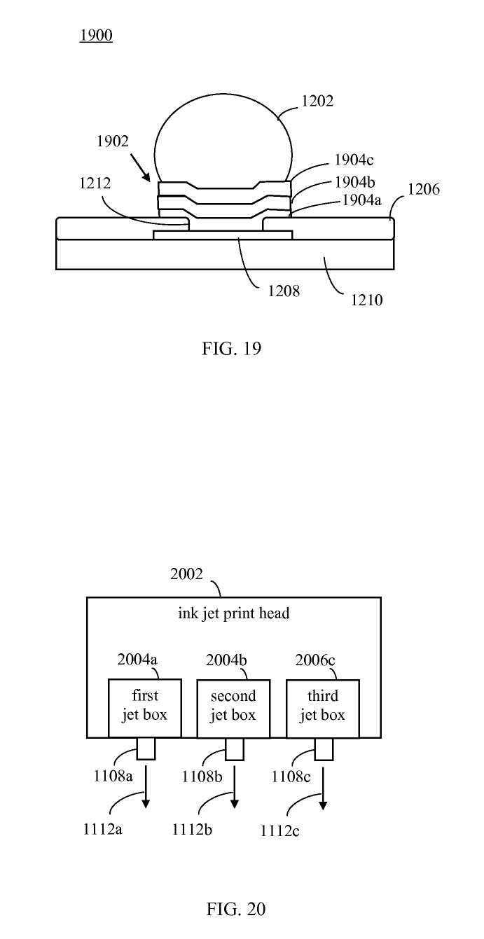

For instance, FIG. 19 shows a portion 1900 of a wafer that includes a multi-layer UBM feature 1902, according to an example embodiment. As shown in FIG. 19, wafer portion 1900 includes wafer substrate 1210, passivation layer 1206, terminal or pad 1208, UBM feature 1902, and bump interconnect 1202. As shown in FIG. 19, UBM feature 1902 includes first-third UBM feature layers 1904a-1904c formed in a stack. First UBM feature layer 1904a is printed on passivation layer 1206 and in contact with terminal 1208 through opening 1212 in passivation layer 1206. Second UBM feature layer 1904b is printed on first UBM feature layer 1904a. Third UBM feature layer 1904c is printed on second UBM feature layer 1904b. Any number of UBM feature layers 1904 may be printed in a stack, including ones, tens, hundreds, or even greater numbers of UBM feature layers 1904. First-third UBM features layers 1904a-1904c may be formed by ink jet printer 1102 by sequential printings of ink 1112. First-third UBM feature layers 1904a-1904c may each be configured to perform a different function (e.g., barrier layers, etc.). Ink jet printer 1102 may print first-third UBM features layers 1904a-1904c using the same ink or different inks. Furthermore, first-third UBM feature layers 1904a-1904c may have the same or different thicknesses.

For example, in an embodiment, ink jet printer 1102 may be configured to accommodate one or more different types of ink 1112 to print corresponding types of UBM features/layers. For instance, FIG. 20 shows a block diagram of an ink jet print head 2002, according to an example embodiment. Ink jet print head 2002 is an example of ink jet print head 1104 shown in FIG. 11. As shown in FIG. 20, ink jet print head 2002 includes first-third jet boxes 2004a-2004c that are each coupled to a corresponding one of print ports 1108a-1108c. Each of first-third jet boxes 2004a-2006c contains and/or sources a corresponding ink that is output (e.g., sprayed) by the corresponding one of print ports 1108a-1108c as first-third inks 1112a-1112c, respectively. Although three jet boxes 2004a-2004c and corresponding inks 1112a-111sc are shown in the example of FIG. 20, any number of jet boxes 2004 and inks 1112 may be present in ink jet print head 2002, in embodiments.

First-third inks 1112a-1112c may be inks that are configured differently, such as containing different materials (e.g., different metals, etc.), different solvents, having different viscosities, etc. First-third inks 1112a-1112c may be output to form corresponding layers of a UBM feature, such as first-third UBM feature layers 1904a-1904c. Additionally and/or alternatively, first-third inks 1112a-1112c may be output to form corresponding features, such as bump interconnects 1202, UBM features 1204, and routing interconnects 1802, respectively. Still further, first-third inks 1112a-1112c may be output to form different types of UBM features at different locations of a wafer.

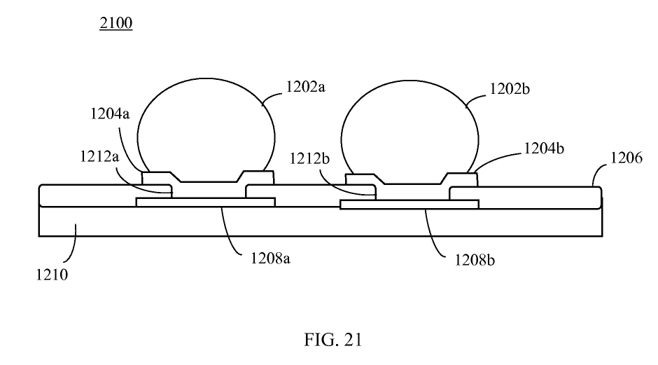

For instance, FIG. 21 shows a cross-sectional view of a wafer portion 2100, according to an example embodiment. As shown in FIG. 21, wafer portion 2100 includes first and second UBM features 1204a and 1204b formed on corresponding terminals 1208a and 1208b at different locations of wafer portion 2100. Bump interconnects 1202a and 1202b are respectively formed on UBM features 1204a and 1204b. In an embodiment, first ink 1112a may be printed on wafer portion 2100 to form UBM feature 1204a and second ink 1112b may be printed on wafer portion 2100 to form UBM feature 1204b, where first and second inks 1112a and 1112b may be different inks that have corresponding characteristics selected to fulfill different UBM requirements. Furthermore, each of UBM features 1204a and 1204b may include one or more UBM feature layers formed by printing the same or different inks.

Printing UBM features as described herein can result in various advantages. Ink jet printing of UBM layers is a relatively simple process that is easy to configure. An ink jet printing process is environmental friendly as nearly no chemicals are involved. No etching or photo development is needed, and no photo resist needed. The ink jet printing process is relatively fast (e.g., may take minutes or hours rather than days). Ink jet printing enables design rules that are comparable or even tighter than conventional techniques. An overall cost is lower (e.g., no expensive mask is needed), and the ink jet printing process has comparable or even greater reliability than conventional techniques.

Furthermore, ink jet printing may enable additional capabilities to a packaging process. For example, ink jet printer 1102 of FIG. 11 may enable the marking of defective and/or good dies of a wafer. For instance, dies may be tested while in wafer form. An indication of any dies that fail test, and thus are considered defective, may be stored in storage in an electronic wafer map. During the UBM feature printing process, rather than printing UBM features, bump interconnects, and/or routing interconnects on the surface of defective dies, no such printing may be performed on the defective die, and instead the defective die may optionally be marked (e.g., with a code or message indicating a defect) on the wafer using the ink jet printer. Furthermore, dies of a wafer can be marked using the ink jet printer to categorize/bin them based on test results or other factors. For example, dies that test as faster than other dies or slower than other dies may be marked as such.

Still further, ink jet printing enables different UBM features and/or different patterns of UBM features to be printed on different regions of a wafer. For instance, in the case of a multipart wafer (MPW), the integrated circuit regions formed on a wafer surface may be different from each other (e.g., different types of chips/dies may be singulated from the wafer). Ink jet printing, as described above, enables different UBM features and/or different arrangements of UBM features to be printed at different locations of a surface of a MPW to accommodate the different integrated circuit regions.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A method, comprising:
receiving a wafer having a surface defined by a plurality of integrated circuit regions, each integrated circuit region having a passivation layer and a plurality of terminals on the surface of the wafer accessible through openings in the passivation layer; and
printing a plurality of under bump metallization (UBM) features in the form of an ink on the surface of the wafer such that each UBM feature is formed electrically coupled with a corresponding terminal of the plurality of terminals.

2. The method of claim 1, wherein said printing comprises:
printing a UBM feature in the form of an ink directly on at least one terminal of the plurality of terminals.

3. The method of claim 1, further comprising:
forming a plurality of routing interconnects on the surface of the wafer such that each routing interconnect has a first portion in contact with a respective terminal of the plurality of terminals and has a second portion that extends over the passivation layer;
wherein said printing comprises
printing a plurality of UBM features in the form of an ink on the plurality of routing interconnects such that each UBM feature is formed on the second portion of a respective routing interconnect of the plurality of routing interconnects.

4. The method of claim 1, further comprising:
forming a plurality of bump interconnects on the plurality of UBM features.

5. The method of claim 4, wherein said forming comprises:
printing the plurality of bump interconnects in the form of an ink on the plurality of UBM features

6. The method of claim 1, wherein the ink includes a metal paste, wherein said printing comprises:
printing the metal paste on the surface of the wafer to form the plurality of UBM features.

7. The method of claim 1, wherein said printing comprises:
ink jet printing the plurality of UBM features on the surface of the wafer.

8. The method of claim 1, wherein said printing comprises:
printing a first ink on a first region of the surface of the wafer to form a first UBM feature electrically coupled to a first terminal; and
printing a second ink on a second region of the surface of the wafer to form a second UBM feature electrically coupled to a second terminal;
wherein the second ink is different from the first ink.

9. The method of claim 1, wherein said printing comprises:
printing a plurality of layers of ink to form at least one of the UBM features.

10. The method of claim 9, wherein said printing comprises:
printing a first ink on the surface of the wafer to form a first layer of the plurality of layers of ink of a first UBM feature; and
printing a second ink on the first layer to form a second layer of the plurality of layers of ink of the first UBM feature;
wherein the second ink is different from the first ink.

11. The method of claim 1, further comprising:
singulating the wafer to form a plurality of integrated circuit packages that each include at least one integrated circuit region of the plurality of integrated circuit regions.

12. An integrated circuit (IC) package, comprising:
an integrated circuit die having a plurality of terminals on a surface of the integrated circuit die;
a passivation layer on the surface of the integrated circuit die having a plurality of openings that provide access to the plurality of terminals; and
a plurality of under bump metallization (UBM) features printed on the integrated circuit die, each UBM feature being electrically coupled to a corresponding terminal of the plurality of terminals, and each UBM feature comprising a solidified ink.

13. The IC package of claim 12, wherein at least one UBM feature is formed directly on a corresponding terminal of the plurality of terminals.

14. The IC package of claim 12, further comprising:
a plurality of routing interconnects each having a first portion and a second portion, the first portion of each routing interconnect being in contact with a respective terminal of the plurality of terminals though a respective opening in the passivation layer and the second portion of each routing interconnect extending over the passivation layer;
wherein each UBM feature is printed on the second portion of a respective routing interconnect of the plurality of routing interconnects.

15. The IC package of claim 12, further comprising:
a plurality of bump interconnects printed on the plurality of UBM features.

16. The IC package of claim 15, wherein the plurality of bump interconnects is arranged in an array of bump interconnects.

17. The IC package of claim 12, wherein the ink includes a metal paste.

18. The IC package of claim 17, wherein the metal paste is a nanopaste.

19. The IC package of claim 18, wherein the metal paste includes at least one of silver or copper.

20. The IC package of claim 12, wherein a first UBM feature of the plurality of UBM features is printed on a first region of the surface of the integrated circuit die using a first ink, the first UBM feature being electrically coupled to a first terminal;
wherein a second UBM feature of the plurality of UBM features is printed on a second region of the surface of the integrated circuit die using a second ink, the second UBM feature being electrically coupled to a second terminal; and
wherein the second ink is different from the first ink.

21. The IC package of claim 12, wherein at least one UBM feature comprises a stack of layers of solidified ink.

22. The IC package of claim 21, wherein a first UBM feature of the plurality of UBM features includes a first UBM layer formed of a first ink printed on the surface of the wafer and a second UBM layer formed of a second ink printed on the first UBM layer;
wherein the second ink is different from the first ink.

23. A system for processing a wafer to form integrated circuit (IC) packages, comprising:
an ink jet printer configured to print a plurality of under bump metallization (UBM) features on the surface of a wafer in the form of an ink, the wafer having a surface defined by a plurality of integrated circuit regions, each integrated circuit region having a passivation layer and a plurality of terminals on the surface of the wafer accessible through openings in the passivation layer.

24. The system of claim 23, further comprising:
a solder bump applicator configured to form a plurality of bump interconnects on the plurality of UBM features such that each bump interconnect of the plurality of bump interconnects is formed on a respective UBM feature.

25. The system of claim 23, wherein the ink jet printer is configured to print using a metal paste as the ink.

26. The system of claim 25, wherein the ink jet printer is configured to print using a nanopaste as the metal paste.

27. The system of claim 25, wherein the metal paste includes at least one of silver or copper.

28. The system of claim 23, wherein the ink jet printer includes a plurality of print heads configured to spray ink.
